(19) United States
(12) Patent Application Publication
(10) Pub. No.: US 2026/0074690 A1
(43) Pub. Date: Mar. 12, 2026

(54) SIGNAL TRANSMISSION INTERFACE

(71) Applicant: Realtek Semiconductor Corp., Hsinchu (TW)

(72) Inventors: Hsiu-Ming Chuang, Hsinchu (TW); Wei-Cheng Tang, Hsinchu (TW)

(73) Assignee: Realtek Semiconductor Corp., Hsinchu (TW)

(21) Appl. No.: 19/309,579

(22) Filed: Aug. 25, 2025

(30) Foreign Application Priority Data
Sep. 11, 2024 (TW) 113134335

(51) Int. Cl. H03K 17/16; H03K 17/284

(52) U.S. Cl. CPC H03K 17/162; H03K 17/284

(57) ABSTRACT

The present invention provides a signal transmission interface including an upper bridge circuit, a lower bridge circuit, a first gate control circuit and a second gate control circuit is disclosed. The upper bridge circuit is configured to selectively couple a supply voltage to an output terminal of the signal transmission interface, and the lower bridge circuit is configured to selectively couple the output terminal of the signal transmission interface to a ground voltage. The first gate control circuit is configured to receive an input signal and control a timing of the input signal being applied to the upper bridge circuit. The second gate control circuit is configured to receive the input signal and control a timing of the input signal being applied to the lower bridge circuit.

### BACKGROUND OF THE INVENTION

### 1. FIELD OF THE INVENTION

The present invention relates to a signal transmission interface.

### 2. DESCRIPTION OF THE PRIOR ART

In general signal transmission interfaces, in order to improve signal reflection issues and enhance signal quality, it is often necessary to limit the rising time and falling time of the transmitted signals within a certain range. Traditionally, this is achieved by controlling the output impedance at the transmission interface. However, this method often fails to effectively regulate the rising and falling times of the output signals smoothly. If the circuit has slower rising or falling times, it will require a larger chip area in the design, subsequently increasing manufacturing costs.

### SUMMARY OF THE INVENTION

Therefore, one of the objectives of this invention is to propose a signal transmission interface that provides smooth rising and falling times for the output signals, to solve the above problems described in the prior art.

According to one embodiment of the present invention, a signal transmission interface comprising an upper bridge circuit, a lower bridge circuit, a first gate control circuit and a second gate control circuit is disclosed. The upper bridge circuit is configured to selectively couple a supply voltage to an output terminal of the signal transmission interface, and the lower bridge circuit is configured to selectively couple the output terminal of the signal transmission interface to a ground voltage. The first gate control circuit is configured to receive an input signal and control a timing of the input signal being applied to the upper bridge circuit. The second gate control circuit is configured to receive the input signal and control a timing of the input signal being applied to the lower bridge circuit.

According to one embodiment of the present invention, a signal transmission interface comprising a plurality of interface circuits connected in parallel is disclosed. Each interface circuit comprises an upper bridge circuit, a lower bridge circuit, a first gate control circuit and a second gate control circuit. The upper bridge circuit is configured to selectively couple a supply voltage to an output terminal of the signal transmission interface, and the lower bridge circuit is configured to selectively couple the output terminal of the signal transmission interface to a ground voltage. The first gate control circuit is configured to receive an input signal and control a timing of the input signal being applied to the upper bridge circuit. The second gate control circuit is configured to receive the input signal and control a timing of the input signal being applied to the lower bridge circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a signal transmission interface according to one embodiment of the present invention.

FIG. 2 is a schematic diagram of a signal transmission interface according to one embodiment of the present invention.

FIG. 3 is a schematic diagram of a signal transmission interface according to one embodiment of the present invention.

FIG. 4 is a schematic diagram of a signal transmission interface according to one embodiment of the present invention.

FIG. 5 is a schematic diagram of the output signal of a signal transmission interface according to one embodiment of the present invention.

FIG. 6 is a schematic diagram of the output signal of a signal transmission interface according to one embodiment of the present invention.

### DETAILED DESCRIPTION

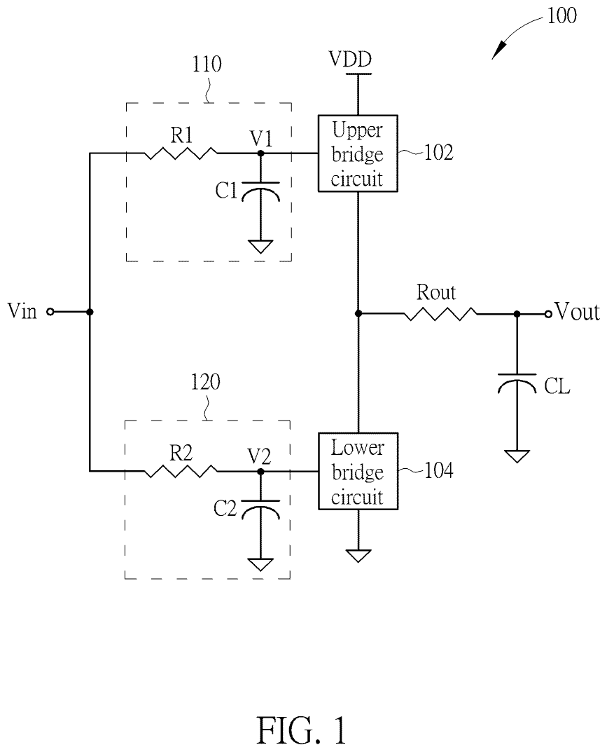

FIG. 1 is a schematic diagram of a signal transmission interface 100 according to one embodiment of the present invention, which is used to receive an input signal Vin and generate an output signal Vout. As shown in FIG. 1, the signal transmission interface 100 includes an upper bridge circuit 102, a lower bridge circuit 104, an output resistor Rout, a load capacitor CL, a gate control circuit 110, and a gate control circuit 120. In this embodiment, the upper bridge circuit 102 is controlled by the input signal Vin to selectively couple a supply voltage VDD to the output terminal of the signal transmission interface 100, that is the upper bridge circuit 102 can be viewed as a switched current source that selectively charges the output terminal of the signal transmission interface 100 by using the supply voltage VDD. The lower bridge circuit 104 is also controlled by the input signal Vin to selectively couple the output terminal of the signal transmission interface 100 to a ground voltage, that is the lower bridge circuit 104 can be viewed as a switched current source that selectively discharges the output terminal of the signal transmission interface 100. In one embodiment, the upper bridge circuit 102 and the lower bridge circuit 104 are not enabled simultaneously. In this embodiment, the upper bridge circuit 102 and the lower bridge circuit 104 can be implemented using one or more transistors, such as one or more bipolar junction transistors (BJTs), one or more metal-oxide-semiconductor field-effect transistors (MOSFETs), or other types of transistors.

The gate control circuit 110 is used to receive the input signal Vin and control the timing of when the input signal Vin is applied to the upper bridge circuit 102. In this embodiment, the gate control circuit 110 functions as a low-pass filter and includes a resistor R1 and a capacitor C1, wherein the resistor R1 is coupled between the input signal Vin and the upper bridge circuit 102, and the capacitor C1 is coupled between the ground voltage and the upper bridge circuit 102. Similarly, the gate control circuit 120 is used to receive the input signal Vin and control the timing of when the input signal Vin is applied to the lower bridge circuit 104. In this embodiment, the gate control circuit 120 also functions as a low-pass filter and includes a resistor R2 and a capacitor C2, wherein the resistor R2 is coupled between the input signal Vin and the lower bridge circuit 104, and the capacitor C2 is coupled between the ground voltage and the lower bridge circuit 104.

In the operation of the signal transmission interface 100, the gate control circuit 110, functioning as a low-pass filter, receives the input signal Vin to generate a filtered input signal V1 that controls the upper bridge circuit 102. Since the rising and falling times of the filtered input signal V1 are longer than those of the input signal Vin, the duration for switching the upper bridge circuit 102 from on to off or from off to on can be effectively controlled. Similarly, the gate control circuit 120, also functioning as a low-pass filter, receives the input signal Vin to generate a filtered input signal V2 that controls the lower bridge circuit 104. The longer rising and falling times of the filtered input signal V2 compared to the input signal Vin allow for effective control of the switching duration of the lower bridge circuit 104 from on to off or from off to on. In the embodiment shown in FIG. 1, by designing the gate control circuits 110 and 120 as low-pass filters, the output signal Vout generated by the signal transmission interface 100 can have longer rising and falling times. This helps to prevent signal reflection during subsequent signal transmission, thereby enhancing signal quality. Additionally, because the signal transmission interface 100 does not require a large chip area in its design, it can provide the output signal Vout with smooth rising and falling times without significantly increasing manufacturing costs.

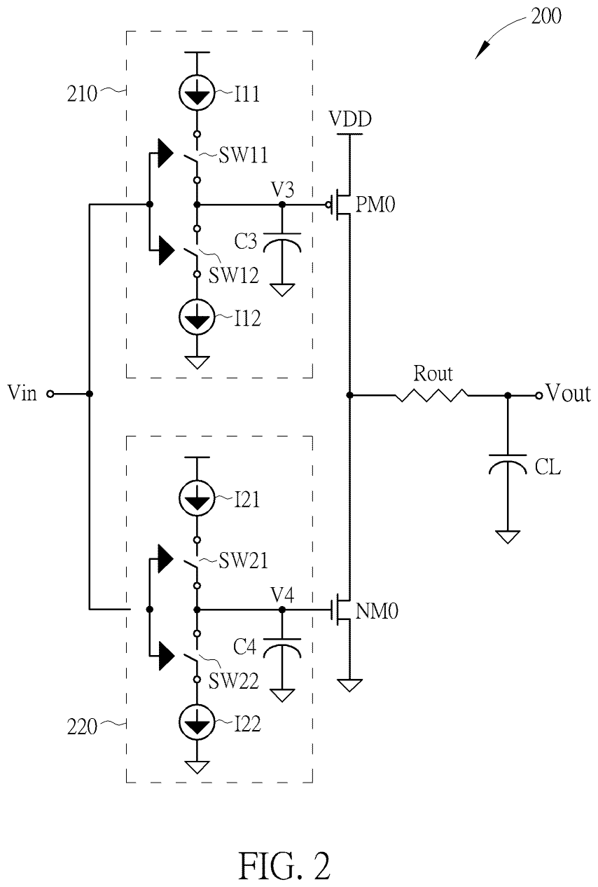

FIG. 2 is a schematic diagram of a signal transmission interface 200 according to one embodiment of the present invention, which is used to receive an input signal Vin and generate an output signal Vout. As shown in FIG. 2, the signal transmission interface 200 includes an upper bridge circuit (a P-type transistor PM0 is used as an example, not a limitation of the invention), a lower bridge circuit (an N-type transistor NM0 is used as an example, not a limitation of the invention), an output resistor Rout, a load capacitor CL, a gate control circuit 210, and a gate control circuit 220. In this embodiment, a gate of the P-type transistor PM0 is coupled to the gate control circuit 210, a source of the P-type transistor PM0 is connected to the supply voltage VDD, and a drain of the P-type transistor PM0 is connected to the output terminal of the signal transmission interface 200. In addition, a gate of the N-type transistor NM0 is coupled to the gate control circuit 220, a source of the N-type transistor NM0 is connected to the ground voltage, and a drain of the N-type transistor NM0 is connected to the drain of the P-type transistor PM0.

The gate control circuit 210 is used to receive the input signal Vin and control the timing of when the input signal Vin is applied to the gate of the P-type transistor PM0. In this embodiment, the gate control circuit 210 functions as a charge pump and includes two current sources I11 and I12, two switches SW11 and SW12, and a capacitor C3. The switch SW11 is controlled by the input signal Vin to selectively couple the current source I11 to the gate of the P-type transistor PM0, while the switch SW12 is controlled by the input signal Vin to selectively couple the current source I12 to the gate of the P-type transistor PM0. The capacitor C3 is coupled between the ground voltage and the gate of the P-type transistor PM0. Similarly, the gate control circuit 220 is used to receive the input signal Vin and control the timing of when the input signal Vin is applied to the gate of the N-type transistor NM0. In this embodiment, the gate control circuit 220 also functions as a charge pump and includes two current sources I21 and I22, two switches SW21 and SW22, and a capacitor C4. The switch SW21 is controlled by the input signal Vin to selectively couple the current source I21 to the gate of the N-type transistor NM0, while the switch SW22 is controlled by the input signal Vin to selectively couple the current source I22 to the gate of the N-type transistor NM0. The capacitor C4 is coupled between the ground voltage and the gate of the N-type transistor NM0.

In the operation of the signal transmission interface 200, the gate control circuit 210, functioning as a charge pump, receives the input signal Vin to generate a processed input signal V3 that controls the P-type transistor PM0 (upper bridge circuit). Since the rising and falling times of the processed input signal V3 are longer than those of the input signal Vin, the duration for switching the P-type transistor PM0 from on to off or from off to on can be effectively controlled. Similarly, the gate control circuit 220, also functioning as a charge pump, receives the input signal Vin to generate a processed input signal V4 that controls the N-type transistor NM0 (lower bridge circuit). Since the rising and falling times of the processed input signal V4 are longer than those of the input signal Vin, allowing for effective control of the switching duration of the N-type transistor NM0 from on to off or from off to on. In the embodiment shown in FIG. 2, by designing the gate control circuits 210 and 220 as charge pumps, the output signal Vout generated by the signal transmission interface 200 can have longer rising and falling times. This helps to prevent signal reflection during subsequent signal transmission, thereby enhancing signal quality. Additionally, because the signal transmission interface 200 does not require a large chip area in its design, it can provide the output signal Vout with smooth rising and falling times without significantly increasing manufacturing costs.

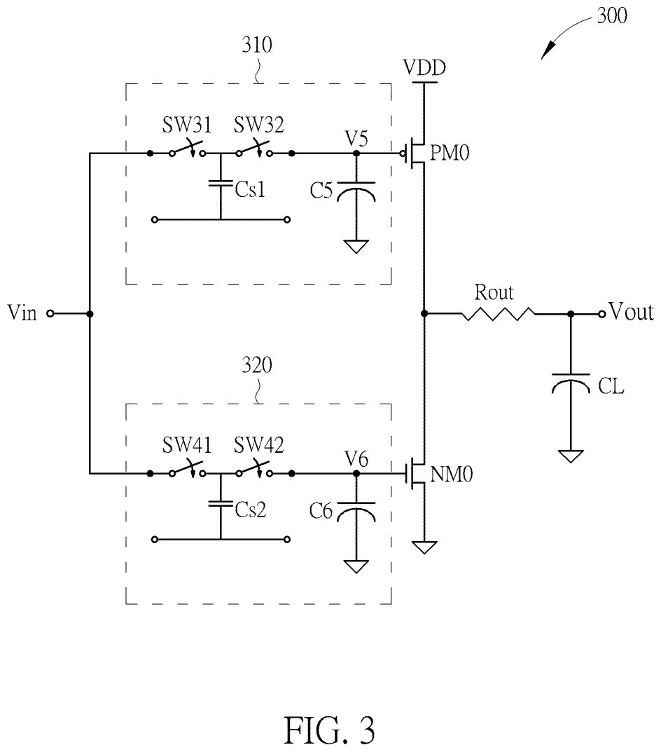

FIG. 3 is a schematic diagram of a signal transmission interface 300 according to one embodiment of the present invention, which is used to receive an input signal Vin and generate an output signal Vout. As shown in FIG. 3, the signal transmission interface 300 includes an upper bridge circuit (a P-type transistor PM0 is used as an example, not a limitation of the invention), a lower bridge circuit (an N-type transistor NM0 is used as an example, not a limitation of the invention), an output resistor Rout, a load capacitor CL, a gate control circuit 310, and a gate control circuit 320.

The gate control circuit 310 is used to receive the input signal Vin and control the timing of when the input signal Vin is applied to the gate of the P-type transistor PM0. In this embodiment, the gate control circuit 310 functions as a switched capacitor and includes two switches SW31 and SW32, a storage capacitor Cs1, and a capacitor C5. The two switches SW31 and SW32 are alternately enabled. When the switch SW31 is enabled and the switch SW32 is disabled, the storage capacitor Cs1 receives the input signal Vin. When the switch SW32 is enabled and the switch SW31 is disabled, the storage capacitor Cs1 shares charge with the capacitor C5, which is coupled between the ground voltage and the gate of the P-type transistor PM0. Similarly, the gate control circuit 320 is used to receive the input signal Vin and control the timing of when the input signal Vin is applied to the gate of the N-type transistor NM0. In this embodiment, the gate control circuit 320 also functions as a switched capacitor and includes two switches SW41 and SW42, a storage capacitor Cs2, and a capacitor C6. The two switches SW41 and SW42 are alternately enabled. When the switch SW41 is enabled and the switch SW42 is disabled, the storage capacitor Cs2 receives the input signal Vin. When the switch SW42 is enabled and the switch SW41 is disabled, the storage capacitor Cs2 shares charge with the capacitor C6, which is coupled between the ground voltage and the gate of the N-type transistor NM0.

In the operation of the signal transmission interface 300, the gate control circuit 310, functioning as a switched capacitor, receives the input signal Vin to generate a processed input signal V5 that controls the P-type transistor PM0 (upper bridge circuit). Since the rising and falling times of the processed input signal V5 are longer than those of the input signal Vin, the duration for switching the P-type transistor PM0 from on to off or from off to on can be effectively controlled.

Similarly, the gate control circuit 320, also functioning as a switched capacitor, receives the input signal Vin to generate a processed input signal V6 that controls the N-type transistor NM0 (lower bridge circuit). The longer rising and falling times of the processed input signal V6 compared to the input signal Vin allow for effective control of the switching duration of the N-type transistor NM0 from on to off or from off to on. In the embodiment shown in FIG. 3, by designing the gate control circuits 310 and 320 as switched capacitors, the output signal Vout generated by the signal transmission interface 300 can have longer rising and falling times. This helps to prevent signal reflection during subsequent signal transmission, thereby enhancing signal quality. Additionally, because the signal transmission interface 300 does not require a large chip area in its design, it can provide the output signal Vout with smooth rising and falling times without significantly increasing manufacturing costs.

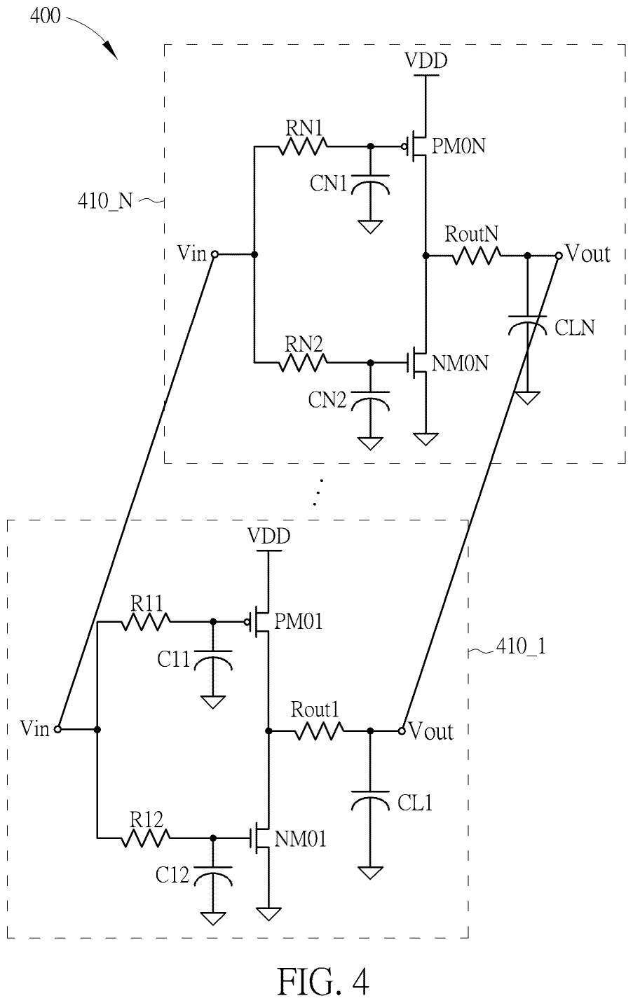

FIG. 4 is a schematic diagram of a signal transmission interface 400 according to one embodiment of the present invention. As shown in FIG. 4, the signal transmission interface 400 includes multiple interface circuits 410_1-410_N connected in parallel, where N is a positive integer greater than 1. In this embodiment, any of the multiple interface circuits 410_1 to 410_N can be the signal transmission interface 100 shown in FIG. 1, the signal transmission interface 200 shown in FIG. 2, or the signal transmission interface 300 shown in FIG. 3. In FIG. 4, the signal transmission interface 100 is used as each of the interface circuits 410_1 to 410_N. That is, the upper bridge circuit (represented by P-type transistor PM01), the lower bridge circuit (represented by N-type transistor NM01), the output resistor Rout1, the load capacitor CL1, the resistors R11 and R12, and the capacitors C11 and C12 in the interface circuit 410_1 function and operate identically to the upper bridge circuit 102, lower bridge circuit 104, output resistor Rout, load capacitor CL, resistors R1 and R2, and capacitors C1 and C2 in the signal transmission interface 100 shown in FIG. 1.

Similarly, the upper bridge circuit (represented by P-type transistor PM0N), the lower bridge circuit (represented by N-type transistor NM0N), the output resistor RoutN, the load capacitor CLN, the resistors RN1 and RN2, and the capacitors CN1 and CN2 in interface circuit 410_N function and operate identically to the upper bridge circuit 102, lower bridge circuit 104, output resistor Rout, load capacitor CL, resistors R1 and R2, and capacitors C1 and C2 in the signal transmission interface 100.

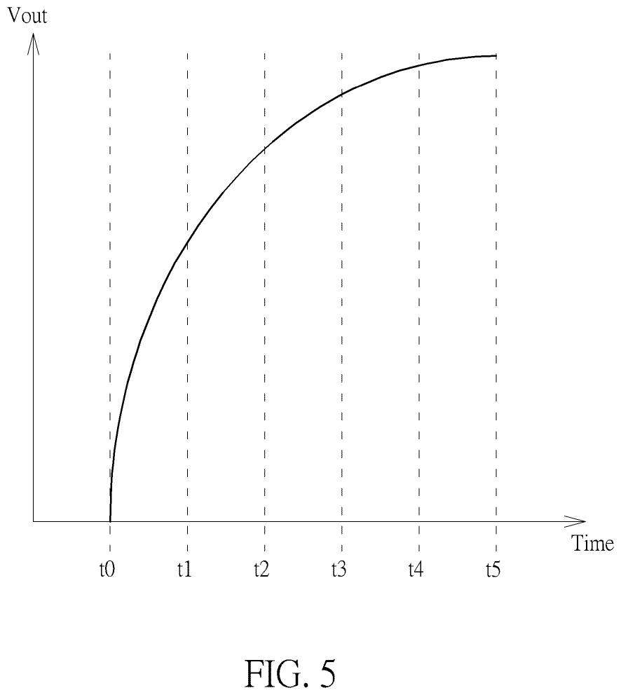

In the embodiment shown in FIG. 4, by connecting multiple interface circuits 410_1 to 410_N in parallel, each of the interface circuits receives the same input signal Vin, and their output terminals are interconnected to generate the output signal Vout. This configuration allows for further control of the rising and falling times of the output signal Vout. For example, referring to FIG. 5, if the signal transmission interface 400 includes ten interface circuits 410_1-410_10, and the input signal Vin switches from a high voltage level to a low voltage level at time t0, the output signal Vout generated by the signal transmission interface 400 will have a stable and longer rising time. This helps to prevent signal reflection during subsequent signal transmission, thereby enhancing signal quality.

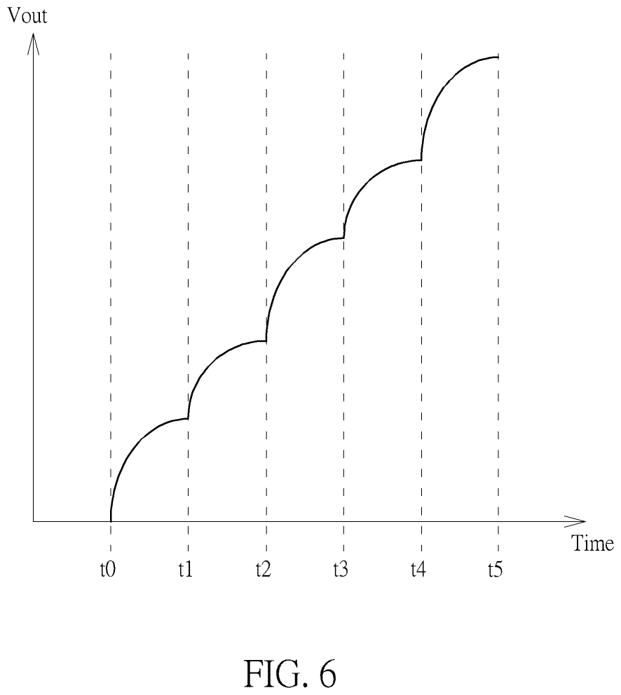

In another embodiment, the P-type and N-type transistors in the interface circuits 410_1 to 410_N have slightly different turn-on/off times, meaning that the delay times of the gate control circuits included in these interface circuits are not identical. Referring to FIG. 6, if the signal transmission interface 400 includes ten interface circuits 410_1-410_10 and the input signal Vin switches from a high voltage level to a low voltage level at time t0, different resistance/capacitance values can be designed for the gate control circuits in interface circuits 410_1 to 410_10, or additional delay circuits can be implemented to create varying turn-on times for the P-type transistors. Specifically, at time t0, the P-type transistors in interface circuits 410_1 and 410_2 begin to enable. At time t1, two additional P-type transistors in interface circuits 410_3 and 410_4 are enabled. At time t2, another two P-type transistors in interface circuits 410_5 and 410_6 are enabled. At time t3, another two P-type transistors in interface circuits 410_7 and 410_8 are enabled. At time t4, the last two P-type transistors in interface circuits 410_9 and 410_10 are enabled. As a result, the output signal Vout generated by the signal transmission interface 400 will have a stable rising time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal transmission interface, comprising:
an upper bridge circuit and a lower bridge circuit, wherein the upper bridge circuit is configured to selectively couple a supply voltage to an output terminal of the signal transmission interface, and the lower bridge circuit is configured to selectively couple the output terminal of the signal transmission interface to a ground voltage;
a first gate control circuit, configured to receive an input signal and control a timing of the input signal being applied to the upper bridge circuit; and
a second gate control circuit, configured to receive the input signal and control a timing of the input signal being applied to the lower bridge circuit.

2. The signal transmission interface of claim 1, wherein the first gate control circuit comprises a first low-pass filter configured to receive the input signal to generate a first filtered input signal to the upper bridge circuit; and the second gate control circuit comprises a second low-pass filter configured to receive the input signal to generate a second filtered input signal to the lower bridge circuit.

3. The signal transmission interface of claim 1, wherein the first gate control circuit comprises a first charge pump configured to receive the input signal to generate a first processed input signal to the upper bridge circuit; and the second gate control circuit comprises a second charge pump configured to receive the input signal to generate a second processed input signal to the lower bridge circuit.

4. The signal transmission interface of claim 1, wherein the first gate control circuit comprises a first switched capacitor configured to receive the input signal to generate a first processed input signal to the upper bridge circuit; and the second gate control circuit comprises a second switched capacitor configured to receive the input signal to generate a second processed input signal to the lower bridge circuit.

5. A signal transmission interface, comprising:
a plurality of interface circuits connected in parallel, each interface circuit comprising:
an upper bridge circuit and a lower bridge circuit, wherein the upper bridge circuit is configured to selectively couple a supply voltage to an output terminal of the signal transmission interface, and the lower bridge circuit is configured to selectively couple the output terminal of the signal transmission interface to a ground voltage;
a first gate control circuit, configured to receive an input signal and control a timing of the input signal being applied to the upper bridge circuit; and
a second gate control circuit, configured to receive the input signal and control a timing of the input signal being applied to the lower bridge circuit.

6. The signal transmission interface of claim 5, wherein the first gate control circuit comprises a first low-pass filter configured to receive the input signal and generate a first filtered input signal to the upper bridge circuit; and the second gate control circuit comprises a second low-pass filter configured to receive the input signal and generate a second filtered input signal to the lower bridge circuit.

7. The signal transmission interface of claim 5, wherein the first gate control circuit comprises a first charge pump configured to receive the input signal and generate a first processed input signal to the upper bridge circuit; and the second gate control circuit comprises a second charge pump configured to receive the input signal and generate a second processed input signal to the lower bridge circuit.

8. The signal transmission interface of claim 5, wherein the first gate control circuit comprises a first switched capacitor configured to receive the input signal and generate a first processed input signal to the upper bridge circuit;
and the second gate control circuit comprises a second switched capacitor configured to receive the input signal and generate a second processed input signal to the lower bridge circuit.

9. The signal transmission interface of claim 5, wherein the upper bridge circuits and lower bridge circuits in the plurality of interface circuits have different turn-on/off times.

10. The signal transmission interface of claim 9, wherein delay times of the first gate control circuits in the plurality of interface circuits are not identical, and delay times of the second gate control circuits in the plurality of interface circuits are not identical.
